(19) United States
(12) Patent Application Publication
(10) Pub. No.: US 2019/0019873 A1
(43) Pub. Date: Jan. 17, 2019

(54) GATE SWITCHING DEVICE AND METHOD MANUFACTURING THE SAME

(71) Applicants: TOYOTA JIDOSHA KABUSHIKI KAISHA, Toyota-shi (JP); KABUSHIKI KAISHA TOYOTA CHUO KENKYUSHO, Nagakute-shi (JP); NATIONAL UNIVERSITY CORPORATION NAGOYA UNIVERSITY, Nagoya-shi (JP)

(72) Inventors: Koji SHIOZAKI, Nagoya-shi (JP); Tetsuo NARITA, Nagakute-shi (JP); Daigo KIKUTA, Nagakute-shi (JP); Kenta CHOKAWA, Nagoya-shi (JP); Kenji SHIRAISHI, Nagoya-shi (JP); Tetsu KACHI, Nagoya-shi (JP)

(73) Assignees: TOYOTA JIDOSHA KABUSHIKI KAISHA, Toyota-shi (JP); KABUSHIKI KAISHA TOYOTA CHUO KENKYUSHO, Nagakute-shi (CN); NATIONAL UNIVERSITY CORPORATION NAGOYA UNIVERSITY, Nagoya-shi (JP)

(21) Appl. No.: 16/016,274

(22) Filed: Jun. 22, 2018

(30) Foreign Application Priority Data
Jul. 14, 2017 (JP) 2017-138421

(51) Int. Cl. H01L 29/51; H01L 29/78; H01L 29/778; H01L 29/423; H01L 29/66; H01L 21/02

(52) U.S. Cl. CPC H01L 29/513; H01L 29/7827; H01L 21/02175; H01L 29/4236; H01L 29/66462; H01L 29/7786

(57) ABSTRACT

A method of manufacturing a gate switching device is provided. The method includes: forming an oxide insulating layer on a gallium nitride semiconductor layer of n-type or i-type; forming a gallium oxide layer at an interface between the oxide insulating layer and the gallium nitride semiconductor layer by heating the oxide insulating layer and the gallium nitride semiconductor layer at a temperature higher than a temperature of the oxide insulating layer and the gallium nitride semiconductor layer in the formation of the oxide insulating layer; and forming a gate electrode opposed to the gallium nitride semiconductor layer via the gallium oxide layer.

### TECHNICAL FIELD

The technique disclosed herein relates to a gate switching device.

### BACKGROUND

In a non-patent literature [symbol] (Yamada et al., (2017) “Comprehensive study on initial thermal oxidation of GaN (0001) surface and subsequent oxide growth in dry oxygen ambient”, Journal of Applied Physics, 121, 035303) describes a technique for forming a gallium oxide layer on a surface of a gallium nitride semiconductor layer such as GaN and AlGaN. Further, this non-patent literature 1 describes using a gallium oxide layer as a gate insulating film of the gate switching device. In the description herein, a switching device provided with a gate electrode insulated from a semiconductor layer by a gate insulating film is termed a gate switching device. When the gallium oxide layer is used as the gate insulating film, an interface state density at an interface between the gallium oxide layer and the gallium nitride semiconductor layer can be made low, by which a characteristic of the gate switching device can be improved.

### SUMMARY

The non-patent literature 1 forms the gallium oxide layer on the gallium nitride semiconductor layer by a thermal oxidation method. However, with this method the gallium oxide layer grows faster at a portion having dislocation defects in the gallium nitride semiconductor layer than at a portion where no dislocation defect exists. Due to this, the gallium oxide layer cannot be formed at a uniform thickness with this method. When the film thickness of the gallium oxide layer is not uniform, issues related to reduction of channel mobility and instability of a gate switching device operation occur. Thus, the disclosure herein provides a technique that enables to manufacture a gate switching device having a superior characteristic by forming a gallium oxide layer at a uniform thickness on a gallium nitride semiconductor layer.

A method disclosed herein is a method of manufacturing a gate switching device. The method may comprise: forming an oxide insulating layer on a gallium nitride semiconductor layer of n-type or i-type; forming a gallium oxide layer at an interface between the oxide insulating layer and the gallium nitride semiconductor layer by heating the oxide insulating layer and the gallium nitride semiconductor layer at a temperature higher than a temperature of the oxide insulating layer and the gallium nitride semiconductor layer in the formation of the oxide insulating layer; and forming a gate electrode opposed to the gallium nitride semiconductor layer via the gallium oxide layer.

In the description herein, a gallium nitride semiconductor layer means a semiconductor layer containing nitride and gallium as its constituent elements. The gallium nitride semiconductor layer includes, for example, GaN, InGaN, and AlGaN. Further, an oxide insulating layer may be constituted of oxide(s) other than gallium oxide. The n-type or i-type gallium nitride semiconductor layer simply needs to be provided within a range where the oxide insulating layer is to be provided, so the n-type or i-type gallium nitride semiconductor layer does not necessarily need to be provided over an entirety of a substrate surface.

In this manufacturing method, the n-type or i-type gallium nitride semiconductor layer is heated in the state where the oxide insulating layer is formed on its surface. When the heating is performed in the state where the n-type or i-type gallium nitride semiconductor layer having the high Fermi level is covered with the oxide insulating layer, following reaction occurs between the gallium nitride semiconductor layer and the oxide insulating layer. By the heating, electrons move from the gallium nitride semiconductor layer to the oxide insulating layer, where oxygen in the oxide insulating layer bonds with the electrons and detaches from the oxide insulating layer. The detached oxygen bonds with gallium in the gallium nitride semiconductor layer at the interface between the oxide insulating layer and the gallium nitride semiconductor layer. As a result, the gallium oxide layer is formed at the interface between the oxide insulating layer and the gallium nitride semiconductor layer. In this reaction, the gallium nitride semiconductor layer is charged positively by losing the electrons. On the other hand, in the above reaction, oxygen vacancies are generated in the oxide insulating layer due to the oxygen detachment therefrom. The oxygen vacancies are charged negatively. Due to this, a dipole is generated across the interface between the oxide insulating layer and the gallium nitride semiconductor layer. Due to the above reaction, formation of the dipole progresses as the gallium oxide layer grows. An electric field generated by the dipole acts in a direction inhibiting movement of the electrons from the gallium nitride semiconductor layer to the oxide insulating layer. Thus, when the above reaction progresses to some degree, the electrons no longer move from the gallium nitride semiconductor layer to the oxide insulating layer, and the above reaction stops. Due to this, a film thickness of the gallium oxide layer does not become thick even at a portion where dislocation defects exist in the gallium nitride semiconductor layer. Accordingly, a significant difference is not generated in the thickness of the gallium oxide layer above the dislocation defects and at a portion where no dislocation defect exists. Thus, according to this manufacturing method, the gallium oxide layer with a uniform film thickness can be formed. As described above, according to this manufacturing method, the gallium oxide layer in contact with the gallium nitride semiconductor layer and having uniform film thickness can be formed as the gate insulating film, and as such, a gate switching device having a superior characteristic can be manufactured.

### BRIEF DESCRIPTION OF DRAWINGS

FIG. 1 is a cross sectional view of a gate switching device.

FIG. 2 is an explanatory diagram of a manufacturing process of the gate switching device.

FIG. 3 is an explanatory diagram of a manufacturing process of the gate switching device.

FIG. 4 is an explanatory diagram of a manufacturing process of the gate switching device.

FIG. 5 is an explanatory diagram of a manufacturing process of the gate switching device.

FIG. 6 is an explanatory diagram of a manufacturing process of the gate switching device.

FIG. 7 is a band diagram of an interface between an oxide insulating layer and a gallium nitride semiconductor layer.

FIG. 8 is a cross sectional view of a gate switching device of a variant.

FIG. 9 is a cross sectional view of a gate switching device of a variant.

FIG. 10 is a cross sectional view of a gate switching device of a variant.

FIG. 11 is a cross sectional view of a gate switching device of a variant.

FIG. 12 is a cross sectional view of a gate switching device of a variant.

### DETAILED DESCRIPTION

Some features of embodiments described hereinbelow will be explained. Each of the features as below is useful independently.

The oxide insulating layer may have a characteristic by which oxygen atoms are discharged from the oxide insulating layer and oxygen vacancies are generated in the oxide insulating layer when the oxide insulating layer is heated. A relationship of E_{V0}−2(E₂−E₁)<3.6 eV may be satisfied, where Eᵥ₀ is energy required to discharge one oxygen atom from the oxide insulating layer, E₁ is an energy level of an unoccupied state generated by the oxygen vacancies, and E₂ is a Fermi level of the gallium nitride semiconductor layer.

According to this configuration, the gallium oxide layer can suitably be formed.

The method may further comprise a step of forming an upper insulating layer on the oxide insulating layer. The upper insulating layer may be amorphous and have a bandgap larger than the gallium oxide layer.

The formation of the upper insulating layer may be carried out prior to the heating for forming the gallium oxide layer, or may be carried out after the heating for forming the gallium oxide layer. Further, in a case where the oxide insulating layer and the gallium nitride semiconductor layer are to be heated in the formation of the upper insulating layer, the step of the formation of the upper insulating layer may serve as the heating for forming the gallium oxide layer.

According to this configuration, leak current between the gate electrode and the gallium nitride semiconductor layer can be suppressed by the upper insulating layer.

The upper insulating layer may be thicker than each of the gallium oxide layer and the oxide insulating layer.

According to this configuration, the leak current flowing between the gate electrode and the gallium nitride semiconductor layer can further be suppressed.

A dielectric constant of the upper insulating layer may be larger than a dielectric constant of the oxide insulating layer.

According to this configuration, when a positive gate voltage is applied to the gate switching device, charges at a higher density in a channel can be accumulated as compared to a case of not having the upper insulating layer, so an on-state resistance for the device being in an on-state can be lowered.

The method may further comprise a step of heating the oxide insulating layer in an atmosphere including oxygen atoms after the formation of the gallium oxide layer.

According to this configuration, oxygen can be supplemented to the oxygen vacancies to vanish the oxygen vacancies. Due to this, the gate switching device operation can be stabilized.

A gate switching device is newly provided herein. The gate switching device may comprise: a gallium nitride semiconductor layer; a gallium oxide layer located on the gallium nitride semiconductor layer; an intermediate insulating layer located on the gallium oxide layer and constituted of an insulating material different from the gallium oxide layer; an upper insulating layer located on the intermediate insulating layer and constituted of an insulating material different from the gallium oxide layer and the intermediate insulating layer; and a gate electrode located on the upper insulating layer. The intermediate insulating layer may be an oxide insulating layer or other insulating layer.

In this gate switching device, its gate insulating film includes the gallium oxide layer, the intermediate insulating layer, and the upper insulating layer. Since a portion of the gate insulating film that is in contact with the gallium nitride semiconductor layer is constituted of the gallium oxide layer, an interface state density at an interface between the gate insulating film and the gallium nitride semiconductor layer is low. Thus, a channel mobility of this gate switching device is high. Further, since two insulating layers are arranged on the gallium oxide layer, leak current flowing between the gate electrode and the gallium nitride semiconductor layer can be suppressed.

In an example of the above-mentioned gate switching device, the upper insulating layer may be an insulating layer having a bandgap larger than the gallium oxide layer and being amorphous.

According to this configuration, the leak current can more effectively be suppressed.

In an example of the above-mentioned gate switching device, the intermediate insulating layer may be an oxide insulating layer having a characteristic by which oxygen atoms are discharged from the oxide insulating layer and oxygen vacancies are generated in the oxide insulating layer when being heated. A relationship of E_{V0}−2(E₂−E₁)<3.6 eV may be satisfied, where Eᵥ₀ is energy required to discharge one oxygen atom from the oxide insulating layer, Eₗ is an energy level of an unoccupied state generated by the oxygen vacancies, and E₂ is a Fermi level of the gallium nitride semiconductor layer.

According to this configuration, the gallium oxide layer can be provided at an interface between the oxide insulating layer and the gallium nitride semiconductor layer.

In an example of the above-mentioned gate switching device, the upper insulating layer may be an amorphous layer in which silicon oxide and aluminum oxide are mixed.

Since a dielectric constant in the amorphous layer having the silicon oxide and the aluminum oxide mixed therein (which is hereinbelow termed an AlSiO layer) is high, the charges can be accumulated at high density in a channel when the positive gate voltage is applied, so the on-state resistance when the gate switching device is in the on-state can be lowered. Further, unlike aluminum oxide, the AlSiO layer maintains its amorphous state even if a high-temperature heating (for example, at 800 to 1000° C.) is carried out thereon, so its insulating performance is high. Further, a silicon oxide layer would have deteriorated insulating performance by reacting with a gallium nitride layer in such a high-temperature heating (800 to 1000° C.), however, this does not occur with the AlSiO layer, thus it can maintain its high insulating performance.

In an example of the above-mentioned gate switching device, the gallium nitride semiconductor layer may be n-type or i-type.

According to this configuration, the gallium oxide layer can be provided by causing the n-type or i-type gallium nitride semiconductor layer having the high Fermi level to react with the oxide insulating layer.

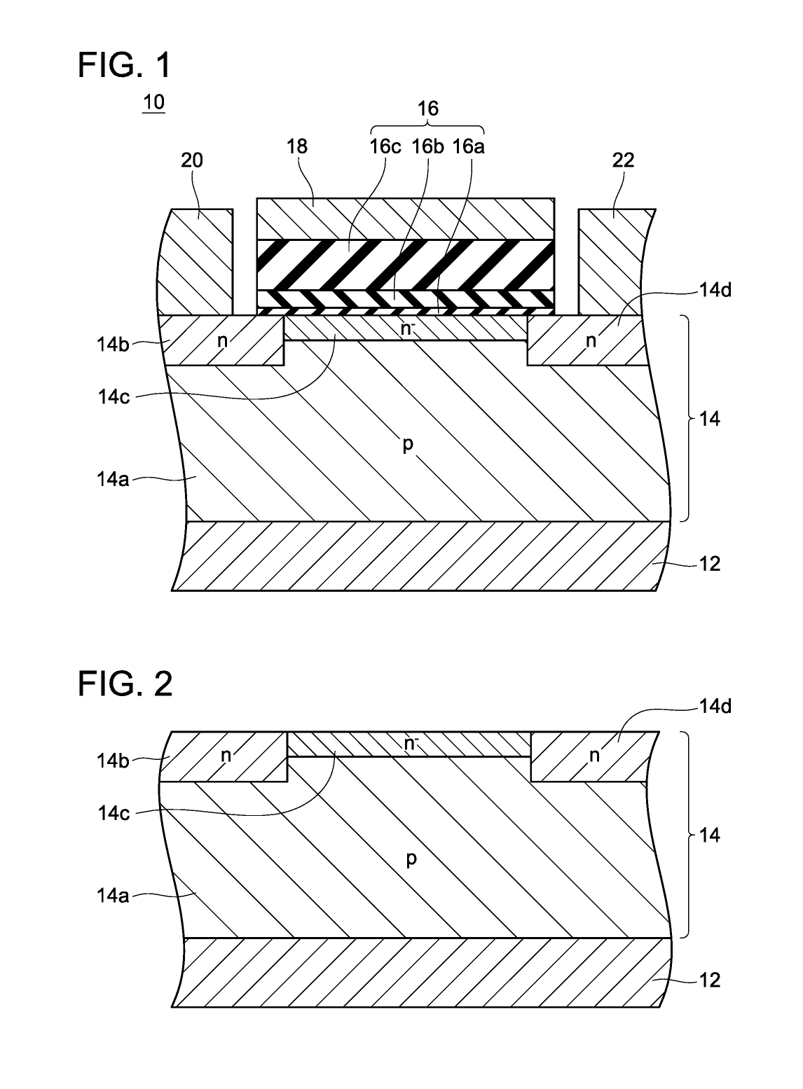

FIG. 1 shows a gate switching device (which is more specifically a MOSFET: metal oxide semiconductor field effect transistor) 10 to be manufactured by a manufacturing method of an embodiment. The gate switching device 10 includes a substrate layer 12, a gallium nitride layer 14, a gate insulating film 16, a gate electrode 18, a source electrode 20 and a drain electrode 22. The substrate layer 12 is constituted of a Si, sapphire, SiC, GaN, or AlN monocrystal. The gallium nitride layer 14 is constituted of a GaN (gallium nitride) monocrystal.

The gallium nitride layer 14 is arranged on the substrate layer 12. The gallium nitride layer 14 includes a body region 14a, a source region 14b, a channel region 14c, and a drain region 14d. The body region 14a is of a p-type. However, the body region 14a may be a semi-insulating layer. The body region 14a is in contact with the substrate layer 12. The source region 14b, the channel region 14c, and the drain region 14d are arranged on the body region 14a. A space is provided between the source region 14b and the drain region 14d, and the channel region 14c is arranged between the source region 14b and the drain region 14d. The channel region 14c is in contact with the source region 14b and the drain region 14d. The source region 14b and the drain region 14d are n-type regions. The channel region 14c is an type (an n-type having a low n-type impurity concentration) region. However, the channel region 14c may be of the i-type.

The source electrode 20 is in contact with the source region 14b. The drain electrode 22 is in contact with the drain region 14d. The source electrode 20 and the drain electrode 22 are constituted of metal.

The gate insulating film 16 covers a surface of the gallium nitride layer 14 over a range encompassing the source region 14b, the channel region 14c, and the drain region 14d. The gate insulating film 16 includes a gallium oxide layer 16a, a silicon oxide layer 16b, and an amorphous layer 16c. The gallium oxide layer 16a is constituted of Ga₂O₃ (gallium oxide). The gallium oxide layer 16a is in contact with the surface of the gallium nitride layer 14 (that is, the source region 14b, the channel region 14c, and the drain region 14d). A thickness of the gallium oxide layer 16a is equal to or less than 1 nm. The silicon oxide layer 16b is constituted of SiO₂ (silicon oxide). The silicon oxide layer 16b is arranged on the gallium oxide layer 16a. The silicon oxide layer 16b is thicker than the gallium oxide layer 16a. A thickness of the silicon oxide layer 16b is 1 to 10 nm. The amorphous layer 16c is constituted of a material in which Al₂O₃ (aluminum oxide) and SiO₂ are mixed, and is amorphous. The amorphous layer 16c has a wider bandgap than the gallium oxide layer 16a. The amorphous layer 16c is thicker than each of the gallium oxide layer 16a and the silicon oxide layer 16b. The amorphous layer 16c has a higher dielectric constant than the silicon oxide layer 16b.

The gate electrode 18 is arranged on the amorphous layer 16c. The gate electrode 18 is constituted of metal. The gate electrode 18 is opposed to the channel region 14c via the gate insulating film 16.

A basic operation of the gate switching device 10 will be described. In a state where a potential of the gate electrode 18 is lower than a threshold, the channel region 14c is depleted by a depletion layer extending from the body region 14a. Thus, in this state, no current flows between the source electrode 20 and the drain electrode 22. When the potential of the gate electrode 18 is raised to a potential that is equal to or greater than the threshold, electrons are drawn to the channel region 14c and a channel is thereby formed. The source region 14b and the drain region 14d are connected by the channel. Due to this, current can be flown between the source electrode 20 and the drain electrode 22 by applying a voltage between the source electrode 20 and the drain electrode 22.

A method of manufacturing the gate switching device 10 will be described. Firstly, as shown in FIG. 2, a wafer including the substrate layer 12 and the gallium nitride layer 14 (that is, the body region 14a, the source region 14b, the channel region 14c, and the drain region 14d) is prepared. The body region 14a, the source region 14b, the channel region 14c, and the drain region 14d may be formed by using conventionally well-known techniques such as epitaxial growth and ion implantation.

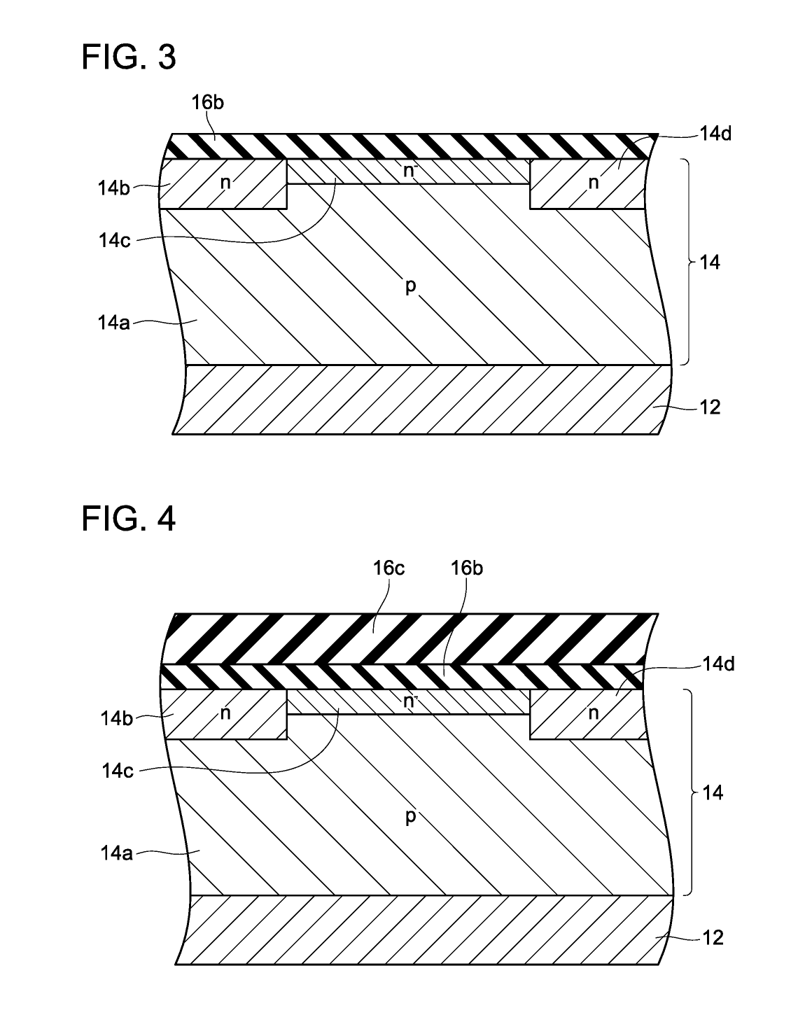

Firstly, as shown in FIG. 3, the silicon oxide layer 16b is formed on the surface of the gallium nitride layer 14. The silicon oxide layer 16b is formed by an atomic layer deposition method (ALD), a chemical vapor deposition method (CVD), or a sputtering method.

Next, as shown in FIG. 4, the amorphous layer 16c is formed on a surface of the silicon oxide layer 16b. The amorphous layer 16c is formed by an atomic layer deposition method, a chemical vapor deposition method, or a sputtering method. The method for forming the amorphous layer 16c may be same as the method for forming the silicon oxide layer 16b, or may be different.

The formation of the silicon oxide layer 16b and the formation of the amorphous layer 16c are performed at a low temperature at a degree by which the gallium nitride layer 14 and the silicon oxide layer 16b do not react with each other.

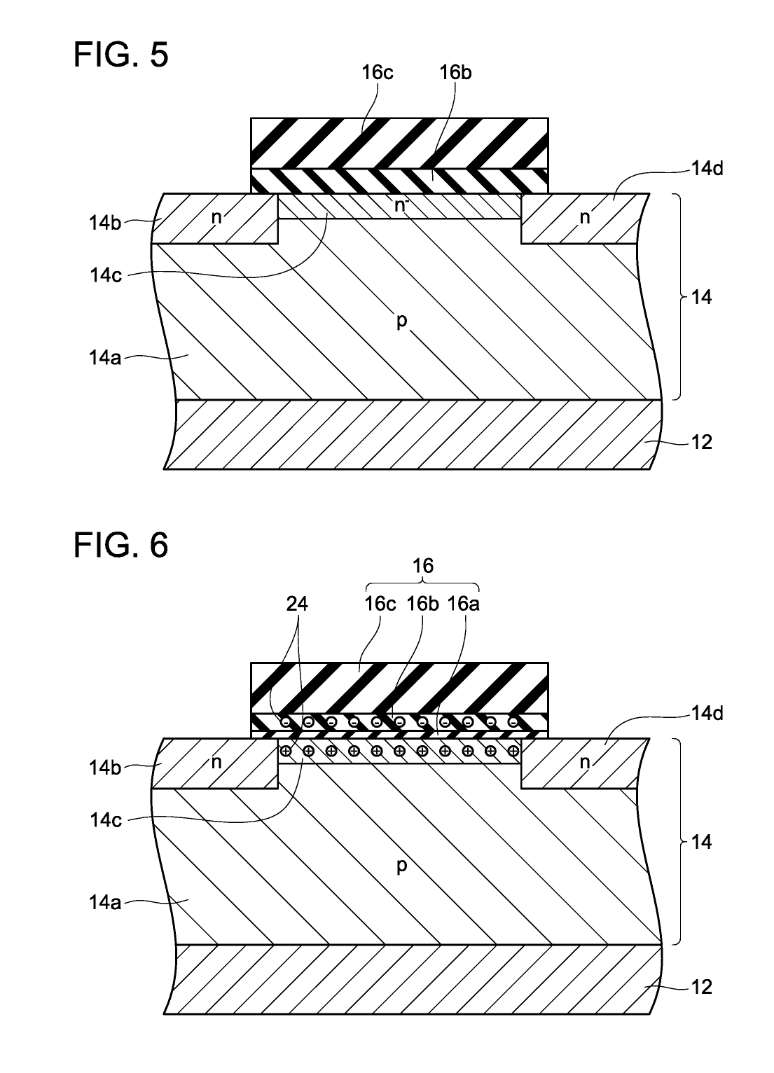

Next, as shown in FIG. 5, the amorphous layer 16c and the silicon oxide layer 16b are partially etched to expose surfaces of the source region 14b and the drain region 14d. The amorphous layer 16c and the silicon oxide layer 16b are left remaining above the channel region 14c (more specifically, above a range encompassing an end portion of the source region 14b, the channel region 14c, and an end portion of the drain region 14d).

Next, an entirety of the wafer is heated at a high temperature. When the wafer is heated, the following reaction occurs at an interface between the silicon oxide layer 16b and the gallium nitride layer 14. When the gallium nitride layer 14 reaches a high temperature, electrons are discharged from the gallium nitride layer 14. Due to this, electrons are supplied to the silicon oxide layer 16b from the gallium nitride layer 14. The electrons supplied to the silicon oxide layer 16b bond with oxygen atoms in the silicon oxide layer 16b. As a result, the oxygen atoms detach from the silicon oxide layer 16b. The detached oxygen atoms bond with gallium atoms in the gallium nitride layer 14 at the interface between the silicon oxide layer 16b and the gallium nitride layer 14. Thus, Ga₂O₃ (gallium oxide) is thereby generated. As a result, as shown in FIG. 6, the gallium oxide layer 16a grows at the interface between the silicon oxide layer 16b and the gallium nitride layer 14. The gate insulating film 16 is completed by the gallium oxide layer 16a being formed.

It should be noted that, in the above reaction, when the electrons are supplied from the gallium nitride layer 14 to the silicon oxide layer 16b, the gallium nitride layer 14 is charged positively. Further, in the above reaction, when the oxygen atoms detach from the silicon oxide layer 16b, oxygen vacancies (holes generated due to the oxygen atoms departing therefrom) are formed in the silicon oxide layer 16b. The oxygen vacancies are charged negatively. Due to this, a dipole 24 is formed across the interface between the silicon oxide layer 16b and the gallium nitride layer 14 by the above reaction. An electric field generated by the dipole 24 acts so as to inhibit movement of the electrons from the gallium nitride layer 14 to the silicon oxide layer 16b. When the above reaction progresses, a density of the dipole 24 increases as the gallium oxide layer 16a grows. Due to this, when the above reaction progresses to some degree, the electric field generated by the dipole 24 becomes stronger, and the electrons can no longer move from the gallium nitride layer 14 to the silicon oxide layer 16b. Thus, the above reaction stops when the reaction progresses to some degree. That is, the growth of the gallium oxide layer 16a stops autonomously when a thickness of the gallium oxide layer 16a reaches a certain thickness. Due to this, according to this method, the gallium oxide layer 16a having a thin film thickness can be formed at a uniform film thickness. The above heating may be performed in an atmosphere that does not contain oxygen atoms in order to suitably form the oxygen vacancies. However, in a case where an influence of the atmosphere is trivial and the oxygen vacancies can be generated suitably, the heating may be performed in an atmosphere including oxygen atoms.

Further, in a case of forming the gallium oxide layer by a thermal oxidization method as in the non-patent literature 1, gallium oxide grows excessively on the dislocation defects of the gallium nitride layer, and grain boundaries of gallium oxide are formed on the dislocation defects. Due to this, the gallium oxide layer cannot be formed at a uniform film thickness. For example, in the thermal oxidization method, the gallium oxide layer grows to the film thickness exceeding 1 nm on the dislocation defects, whereas the film thickness of the gallium oxide layer is less than 1 nm at portions where the dislocation defects do not exist. Thus, in the thermal oxidation method, flatness at the interface between the gallium oxide layer and the gallium nitride layer is inferior. Contrary to this, in the method of the present embodiment, the growth of the gallium oxide layer 16a autonomously stops by the electric field generated by the dipole 24, so a significant difference in the film thickness of the gallium oxide layer 16a is not generated between the portion where the dislocation defects exist and the portion where the dislocation defects does not exist. Due to this, a gallium oxide layer 16a having a uniform film thickness can be formed. For example, according to the method of the present embodiment, the thickness of the gallium oxide layer 16a can be made less than 1 nm regardless of locations therein. Due to this, according to the method of the present embodiment, the interface between the gallium oxide layer 16a and the gallium nitride layer 14 can be flattened.

After having formed the gallium oxide layer 16a, the wafer is then heated in gas containing oxygen atoms. The gas containing oxygen atoms may be oxygen gas (O₂), may be gas containing oxygen radicals, or may be high-pressure water vapor (H₂O). When the wafer is heated in the gas containing oxygen atoms, oxygen in the gas is supplemented to the oxygen vacancies in the silicon oxide layer 16b and thereby the oxygen vacancies vanish. Due to this, the density of the oxygen vacancies in the silicon oxide layer 16b thereby decreases.

Next, the gate electrode 18 is formed on the surface of the amorphous layer 16c. Then, the source electrode 20 is formed on the surface of the source region 14b, and the drain electrode 22 is formed on the surface of the drain region 14d. The gate switching device 10 shown in FIG. 1 is completed by the foregoing processes.

As described above, according to this manufacturing method, the gallium oxide layer 16a can be formed at the portion of the gate insulating film 16 that is in contact with the gallium nitride layer 14. Since an interface state density at the interface between the gallium oxide layer 16a and the gallium nitride layer 14 is low, Coulomb scattering is less likely to occur in the channel formed in the channel region 14c. Thus, the channel mobility of the gate switching device 10 can be improved. Moreover, according to this method, the gallium oxide layer 16a can be formed at a uniform film thickness, and the interface between the gallium oxide layer 16a and the gallium nitride layer 14 can be flattened than in the conventional technique. Thus, interface roughness scattering is less likely to occur in the channel formed in the channel region 14c. Due to this, the channel mobility of the gate switching device 10 can further be improved. Thus, according to this method, an on-state resistance of the gate switching device 10 can be reduced.

Further, as aforementioned, since the growth of the gallium oxide layer 16a stops autonomously in this manufacturing method, variation is less likely to occur in the thickness of the gallium oxide layer 16a upon the mass production of the gate switching device 10. Thus, according to this manufacturing method, variation in characteristics among the mass-produced gate switching devices 10 can be suppressed.

Further, as aforementioned, in the case of forming the gallium oxide layer by the thermal oxidization method, the grain boundaries are formed in the gallium nitride layer at positions above the dislocation defects in the gallium nitride layer. When the gallium oxide layer includes such grain boundaries, breakdown voltage of the gallium oxide layer is deteriorated. Further, in a case of forming another insulating layer on the gallium oxide layer, pinholes are easily formed in the insulating layer above the grain boundaries. Due to this, breakdown voltage of the gate insulating film is deteriorated. Contrary to this, according to the manufacturing method of the present embodiment, excessive growth of the gallium oxide layer 16a does not occur above the dislocation defects of the gallium nitride layer 14, so the grain boundaries are less likely to be formed in the gallium oxide layer 16a. Due to this, according to the manufacturing method of the present embodiment, the breakdown voltage of the gate insulating film 16 can be improved.

Further, in the aforementioned manufacturing method, the amorphous layer 16c is formed on the silicon oxide layer 16b. Since the gallium oxide layer 16a is polycrystal, leak current easily flows through crystalline grain boundaries. Further, the silicon oxide layer 16b deposited at a low temperature at a degree by which reaction with the gallium nitride layer 14 does not occur does not have sufficient insulating performance, so the leak current easily occurs through defects in the insulating film. Compared to this, the amorphous layer 16c in which the silicon oxide and the aluminum oxide are mixed does not have such crystalline grain boundaries due to being amorphous, and further, it is capable of forming a fine film at a lower temperature than the silicon oxide layer and has high insulating performance. Further, since the amorphous layer 16c has a large bandgap, breakdown voltage of the material itself is high. Due to this, it becomes more difficult for the leak current to flow through the gate insulating film 16 by providing the amorphous layer 16c. Due to this, the leak current between the gate electrode 18 and the gallium nitride layer 14 can be suppressed. Especially since the amorphous layer 16c is thicker than both the gallium oxide layer 16a and the silicon oxide layer 16b, the leak current can more effectively be suppressed.

Further, in the aforementioned manufacturing method, the amorphous layer 16c is formed by a material having a higher dielectric constant than each of the gallium oxide layer 16a and the silicon oxide layer 16b. Due to this, when a potential of the gate electrode 18 is raised, carriers accumulate at high density in the channel. By the above configuration, an on-state resistance upon when the device is in an on-state can be lowered.

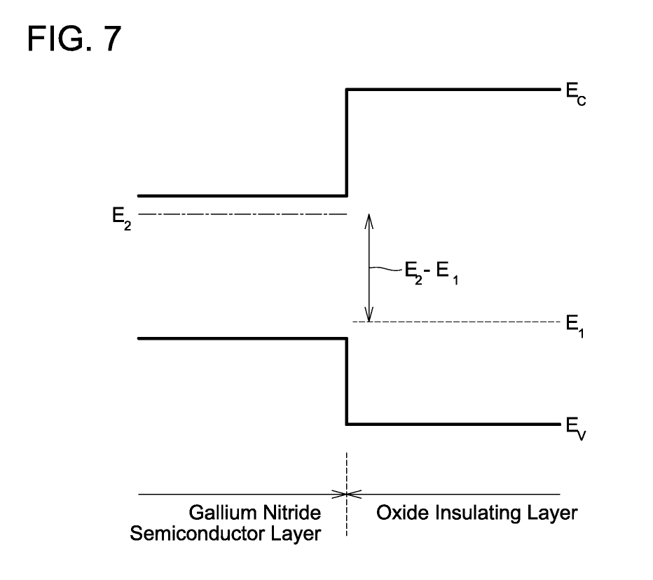

FIG. 7 shows a band diagram at an interface between a gallium nitride semiconductor layer (which is the gallium nitride layer 14 in the above embodiment) and an oxide insulating layer (which is the silicon oxide layer 16b in the above embodiment). In FIG. 7, a reference sign E_{C} indicates a level at a lower end of a conduction band, a reference sign E_{V} indicates a level at an upper end of a valence band, a reference sign E₁ indicates an unoccupied defect level of oxygen vacancies in the oxide insulating layer, and a reference sign E₂ indicates a Fermi level of the gallium nitride semiconductor layer. An energy gain E_{gain} upon when the gallium oxide layer is formed satisfies a relationship of E_{gain}=2(E₂−E₁)+E_{Ga2O3}−E_{V0}. Here, a reference sign E_{Ga2O3} is energy obtained upon when gallium oxide is formed, which is about 3.6 eV. Further, E_{V0} is energy that is required for discharging one oxygen atom from the oxide insulating layer. E_{V0} and E₁ are values unique to the oxide insulating layer, and are determined according to a type of the oxide insulating layer to be used. Reaction for forming the gallium oxide layer by heating can take place in a case where a relationship of E_{gain}>0 is satisfied. That is, the reaction for forming the gallium oxide layer by heating can take place in a case where a relationship of E_{V0}−2(E₂−E₁)<3.6 eV is satisfied. In the case of using the n-type or i-type gallium nitride layer 14 as the gallium nitride semiconductor layer and the silicon oxide layer 16b as the oxide insulating layer, E_{V0}=4.7 eV and E₂−E₁=2.8 eV are met, therefore the relationship of E_{V0}−2(E₂−E₁)<3.6 eV is satisfied. Accordingly, the gallium oxide layer 16a can be formed.

In the aforementioned embodiment, in a case where a surface layer portion of the gallium nitride semiconductor layer (that is, the channel region 14c) is of a p-type, E_{V0}−2(E₂−E₁)>3.6 eV is obtained due to its E₂ being smaller by about 3.1 eV as compared to the n-type and the i-type, as a result of which the energy gain is not obtained and thus the gallium oxide formation does not take place. In other words, since the energy level of E₁ is higher than the Fermi level of the p-type gallium nitride semiconductor, electron movement from the gallium nitride semiconductor to the oxide insulating layer does not take place, and thus the reaction does not occur. Thus, in the case of using silicon oxide as the oxide insulating layer, the gallium oxide layer 16a can be formed by using the n-type or i-type as the gallium nitride semiconductor layer constituting the channel region 14c.

In the aforementioned embodiment, the process to form the amorphous layer 16c is carried out prior to the heating process for forming the gallium oxide layer 16a. However, the process to form the amorphous layer 16c may be carried out after the heating process for forming the gallium oxide layer 16a. Further, in a case where the wafer is heated to a high temperature in the process to form the amorphous layer 16c, the gallium oxide layer 16a may be formed by this heating. That is, the process to form the amorphous layer 16c may serve as the heating process for forming the gallium oxide layer 16a.

Further, in the aforementioned embodiment, the heating is performed in the atmosphere containing the oxygen atoms to vanish the oxygen vacancies. By vanishing the oxygen vacancies, operation stability of the gate switching device 10 can be improved. However, in a case where an influence of the oxygen vacancies on the characteristics of the gate switching device is trivial, the heating for vanishing the oxygen vacancies does not have to be performed.

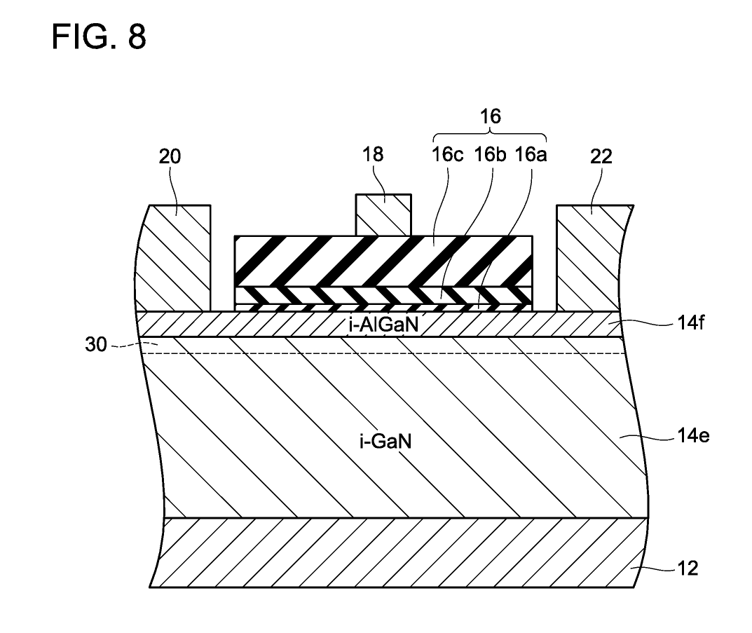

Further, the forming method of the gate insulating film 16 in the aforementioned embodiment may be used for gate switching devices shown in FIGS. 8 to 12. In FIGS. 8 to 12, portions of the gate switching devices corresponding to those of FIG. 1 are given the same reference signs as in FIG. 1.

FIG. 8 shows a HEMT (high electron mobility transistor) that constitutes its channel by two-dimensional electron gas 30. In the HEMT of FIG. 8, an i-type GaN layer 14e and an i-type AlGaN layer 14f are arranged on the substrate layer 12. The GaN layer 14e is arranged on the substrate layer 12, and the AlGaN layer 14f is arranged on the GaN layer 14e. The AlGaN layer 14f forms a heterojunction with the GaN layer 14e. In the GaN layer 14e, the two-dimensional electron gas 30 is formed in a vicinity of an interface between the GaN layer 14e and the AlGaN layer 14f. The two-dimensional electron gas 30 immediately below the gate electrode 18 vanishes and appears according to the potential of the gate electrode 18. When the two-dimensional electron gas 30 is caused to appear immediately below the gate electrode 18 by controlling the potential of the gate electrode 18, current can be flown from the drain electrode 22 to the source electrode 20. The gate insulating film 16 has the structure in which the gallium oxide layer 16a, the silicon oxide layer 16b, and the amorphous layer 16c are layered, similar to the gate switching device of FIG. 1. In the HEMT as well, the gallium oxide layer 16a having the uniform film thickness can be formed in contact with the AlGaN layer 14f by the same method as in the aforementioned embodiment. Due to this, the channel mobility can be improved, and the HEMT operation can be stabilized. It should be noted that, in the HEMT, the channel (that is, the two-dimensional electron gas 30) is not in contact with the gallium oxide layer 16a, however, since the channel is arranged at a position close to the gallium oxide layer 16a, carrier behaviors at the channel are influenced by surface roughness of an interface between the gallium oxide layer 16a and the AlGaN layer 14f. Thus, in the HEMT as well, the film thickness of the gallium oxide layer 16a can be made uniform to flatten the interface between the gallium oxide layer 16a and the AlGaN layer 14f to improve the channel mobility.

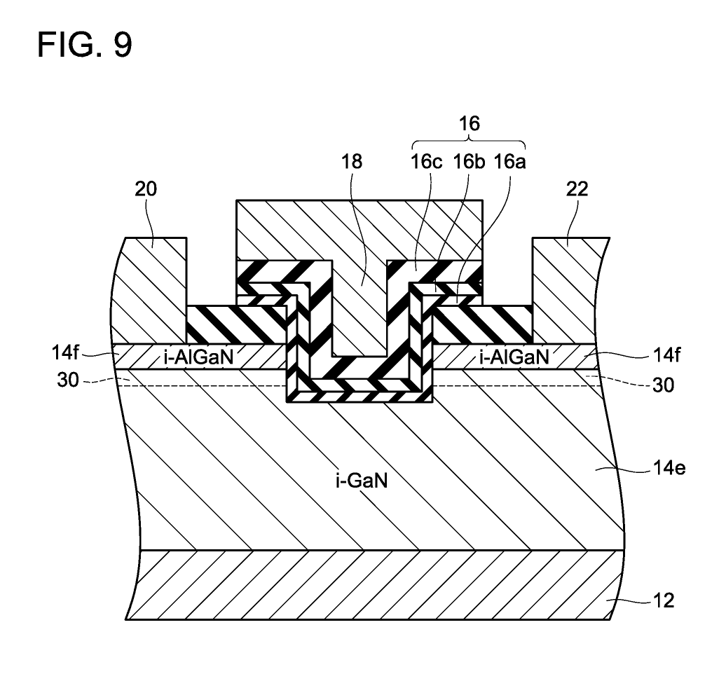

FIG. 9 is a gate switching device that arranges the i-type GaN layer 14e immediately below a trench-type gate electrode 18 and other current paths are provided by a HEMT structure (the two-dimensional electron gas 30 at the interface between the i-type AlGaN layer 14f and the GaN layer 14e). When the potential of the gate electrode 18 is raised higher than a threshold, a channel is generated in the GaN layer 14e in a range adjacent to the gallium oxide layer 16a. When the channel is formed, the current can be flown from the drain electrode 22 to the source electrode 20 via the channel and the two-dimensional electron gas 30. In the gate switching device of FIG. 9 as well, substantially the same effect as the case of manufacturing the gate switching device of FIG. 1 can be achieved by forming the gallium oxide layer 16a by the same method as that of the gate switching device of FIG. 1.

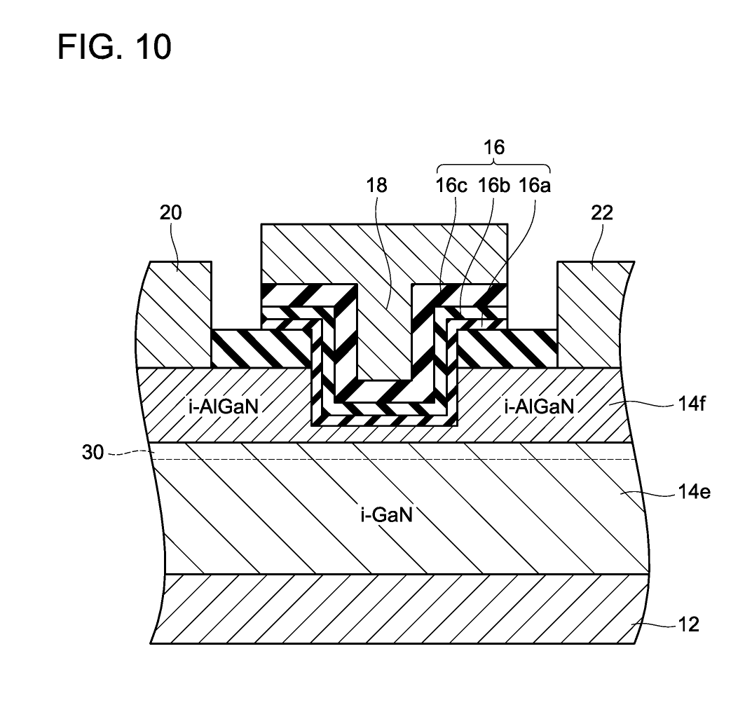

FIG. 10 is a HEMT provided with the trench-type gate electrode 18. The two-dimensional dimensional electron gas 30 immediately below the gate electrode 18 vanishes and appears by controlling the potential of the gate electrode 18. In the HEMT of FIG. 10 as well, substantially the same effect as the case of manufacturing the gate switching device of FIG. 1 can be achieved by forming the gallium oxide layer 16a by the same method as that of the aforementioned embodiments.

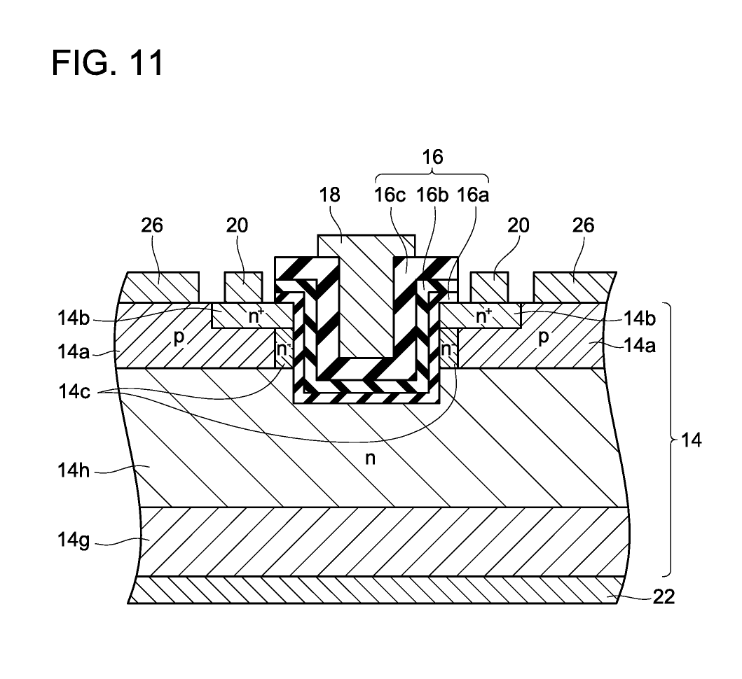

FIG. 11 is a vertical-type gate switching device (MOSFET), and includes the channel region 14c that extends vertically along a trench. When the potential of the gate electrode 18 is raised higher than the threshold, a channel is formed in the channel region 14c. The current flows from the drain electrode 22 to the source electrode 20 through a GaN layer 14g, an n-type GaN layer 14h, the channel, and the source region 14b. A reference sign 26 in FIG. 11 is an electrode for stabilizing the potential of the body region 14a. In the gate switching device of FIG. 11 as well, substantially the same effect as the case of manufacturing the gate switching device of FIG. 1 can be achieved by forming the gallium oxide layer 16a by the same method as that of the gate switching device of FIG. 1.

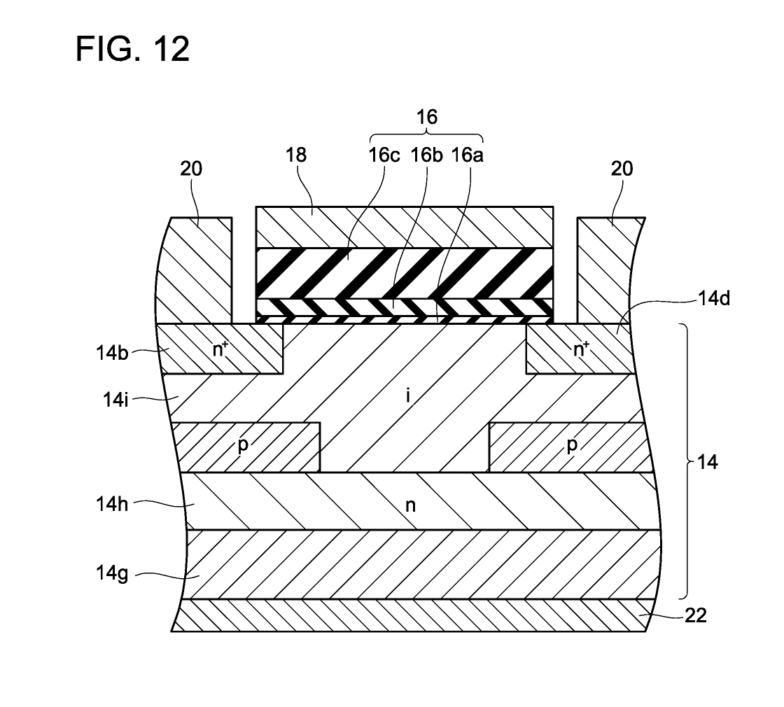

FIG. 12 is a vertical-type gate switching device (MOSFET). When the potential of the gate electrode 18 is raised higher than the threshold, a channel is formed in an i-type GaN layer 14i within a range adjacent to the gallium oxide layer 16a. The current flows from the drain electrode 22 to the source electrode 20 through the GaN layer 14g, the n-type GaN layer 14h, the GaN layer 14i, the channel 14c, and the source region 14b. In the gate switching device of FIG. 12 as well, substantially the same effect as the case of manufacturing the gate switching device of FIG. 1 can be achieved by forming the gallium oxide layer 16a by the same method as that of the gate switching device of FIG. 1.

Specific examples of the present disclosure have been described in detail, however, these are mere exemplary indications and thus do not limit the scope of the claims. The art described in the claims include modifications and variations of the specific examples presented above. Technical features described in the description and the drawings may technically be useful alone or in various combinations, and are not limited to the combinations as originally claimed. Further, the art described in the description and the drawings may concurrently achieve a plurality of aims, and technical significance thereof resides in achieving any one of such aims.

What is claimed is:

1. A method of manufacturing a gate switching device, the method comprising:
forming an oxide insulating layer on a gallium nitride semiconductor layer of n-type or i-type;
forming a gallium oxide layer at an interface between the oxide insulating layer and the gallium nitride semiconductor layer by heating the oxide insulating layer and the gallium nitride semiconductor layer at a temperature higher than a temperature of the oxide insulating layer and the gallium nitride semiconductor layer in the formation of the oxide insulating layer; and
forming a gate electrode opposed to the gallium nitride semiconductor layer via the gallium oxide layer.

2. The method of claim 1, wherein
the oxide insulating layer has a characteristic by which oxygen atoms are discharged from the oxide insulating layer and oxygen vacancies are generated in the oxide insulating layer when the oxide insulating layer is heated, and
a relationship of E_{V0}−2(E₂−E₁)<3.6 eV is satisfied, where Eᵥ₀ is energy required to discharge one oxygen atom from the oxide insulating layer, E₁ is an energy level of an unoccupied state generated by the oxygen vacancies, and B₂ is a Fermi level of the gallium nitride semiconductor layer.

3. The method of claim 1, further comprising:
forming an upper insulating layer on the oxide insulating layer, the upper insulating layer being amorphous and having a bandgap larger than the gallium oxide layer.

4. The method of claim 3, wherein the upper insulating layer is thicker than each of the gallium oxide layer and the oxide insulating layer.

5. The method of claim 3, wherein a dielectric constant of the upper insulating layer is larger than a dielectric constant of the oxide insulating layer.

6. The method of claim 1, further comprising:
heating the oxide insulating layer in an atmosphere including oxygen atoms after the formation of the gallium oxide layer.

7. A gate switching device comprising:
a gallium nitride semiconductor layer;
a gallium oxide layer located on the gallium nitride semiconductor layer;
an intermediate insulating layer located on the gallium oxide layer and constituted of an insulating material different from the gallium oxide layer;
an upper insulating layer located on the intermediate insulating layer and constituted of an insulating material different from the gallium oxide layer and the intermediate insulating layer; and
a gate electrode located on the upper insulating layer.

8. The gate switching device of claim 7, wherein the upper insulating layer is an insulating layer having a bandgap larger than the gallium oxide layer and being amorphous.

9. The gate switching device of claim 7, wherein
the intermediate insulating layer is an oxide insulating layer having a characteristic by which oxygen atoms are discharged from the oxide insulating layer and oxygen vacancies are generated in the oxide insulating layer when being heated, and
a relationship of E_{V0}−2(E₂−E₁)<3.6 eV is satisfied, where Eᵥ₀ is energy required to discharge one oxygen atom from the oxide insulating layer, E₁ is an energy level of an unoccupied state generated by the oxygen vacancies, and E₂ is a Fermi level of the gallium nitride semiconductor layer.

10. The gate switching device of claim 7, wherein the upper insulating layer is an amorphous layer in which silicon oxide and aluminum oxide are mixed.
